(19) United States
(12) Patent Application Publication
(10) Pub. No.: US 2020/0385860 A1
(43) Pub. Date: Dec. 10, 2020

(54) METAL OXIDE THIN FILM FORMATION APPARATUS AND METAL OXIDE THIN FILM FORMATION METHOD

(71) Applicant: YAMAGATA UNIVERSITY, Yamagata-shi (JP)

(72) Inventors: Fumihiko HIROSE, Yonezawa-shi (JP); Makoto ISHIKAWA, Yonezawa-shi (JP); Masanori MIURA, Yonezawa-shi (JP)

(21) Appl. No.: 16/763,812

(22) PCT Filed: Nov. 15, 2018
(86) PCT No.: PCT/JP2018/042336

§ 371 Date: May 13, 2020

(30) Foreign Application Priority Data
Nov. 15, 2017 (JP) 2017-220417

(51) Int. Cl. C23C 16/40; C23C 16/44; C23C 16/455

(52) U.S. Cl. CPC C23C 16/403; C23C 16/45544; C23C 16/4412; C23C 16/4417

(57) ABSTRACT

A disclosed metal oxide thin film formation apparatus is equipped with: a vacuum vessel; a treatment vessel which is disposed inside the vacuum vessel, is capable of horizontally rotating about a central axis inclined from the horizontal direction, and has an opening on one end face thereof; an oxidizing gas supply device which supplies an oxidizing gas into the vacuum vessel; an organic metal gas supply device which is inserted inward from the opening and supplies an organic metal gas; and a control unit for executing a series of steps, namely, an organic metal gas supply step, a first gas discharge step, an oxidizing gas supply step, and a second gas discharge step, and repeating the series of steps through for a predetermined number of times in accordance with the film thickness of the metal oxide thin film to be formed on the surfaces of microparticles.

### TECHNICAL FIELD

The present invention relates to a metal oxide thin film formation apparatus and a metal oxide thin film formation method that are used in the field of production of inks, water-soluble pastes, etc. that use metal powder materials. More particularly, the invention relates to a metal oxide thin film formation apparatus and a metal oxide thin film formation method that are used to facilitate production of the inks and water-soluble pastes by forming a metal oxide coating on the surface (i.e., a concept including a plurality of specific surfaces) of finely-divided (hereinafter referred to simply as “fine”) particles of a metal powder material to improve wettability of the fine particles.

### BACKGROUND ART

Fine metal particles of micrometer to nanometer size have, in addition to their intrinsic physical properties, physical properties, mechanical properties, formability, etc. that are specific to their small size and are therefore used as metal powder materials in many areas. For example, since nanosize gold or silver particles, which are one type of metal powder material, have good electrical conductivity, they are used for forming a metal wiring pattern. Specifically, these particles are mixed with water, an organic solvent, etc. to disperse them therein, thereby obtaining an ink, and the ink is used to form a metal wiring pattern using an ink-jet printer.

Titanium oxide in the form of particles with a diameter of about 100 nm has the ability to purify water by oxidizing organic materials and is used as a photocatalyst dispersed in water. By reducing the size of fine titanium oxide particles to a submicron level, the ratio of their surface to their volume can be increased, and such fine titanium oxide particles are used, for example, to increase the efficiency of reaction.

When zirconia particles are kneaded with a material such as a resin or a plastic material, the refractive index of the mixture can be increased, and these zirconia particles are used to, for example, reduce the thickness of lenses.

The above various fine metal particles are used by dissolving or mixing in or with water, oil, an organic material, a solvent, a resin, etc. For example, by dissolving or mixing the fine metal particles in or with a solvent to form a paste, the application of the fine metal particles using, for example, blade coating is facilitated. By forming an ink in a similar manner, the formation of a coating film by brush coating, spraying, etc. is facilitated. By dissolving or mixing the fine metal particles in or with a resin, the hardness and optical properties of the plastic product or its heat conductivity can be improved, and the forming of the plastic material is facilitated.

Against the above backdrop, it is important that, when a metal powder material and another powder material are used in combination, the contact properties between a solvent and the surface of the fine particles must be improved. For example, to disperse a powder material in water, it is necessary that the surface of the fine particles be hydrophilized so that, when they come into contact with water, they are not repelled by water. To form such a hydrophilic surface, it is necessary that the fine particles be subjected to hydrophilization treatment for forming, for example, hydroxyl groups (OH groups) on their surface to promote hydrogen bonding with water. To enhance the affinity between a powder material and an oil or resin, it is necessary to impart oleophilicity to the surface of the fine particles. To form an oleophilic surface, the surface of the fine particles is subjected to oleophilization treatment for forming hydrocarbon groups (such as CH₃ groups) on the surface of the fine particles. By subjecting the surface of the fine particles to the oleophilization treatment, the powder material can be easily dispersed in, for example, a resin. When a powder material is not appropriately surface-treated, there arises a problem that the powder material dissolved in or mixed with any of the above materials ooze out to the surface or aggregate to form solids.

In one specific example of the hydrophilization treatment method, the surface of fine particles is subjected to ozone treatment or plasma treatment to oxidize the surface of the fine particles and form OH groups on the surface. However, this method is not easily applicable to powder materials composed of fine particles with surfaces that resist oxidation (e.g., carbon powder) or powder materials whose characteristics are changed by surface treatment (e.g., resin powder).

In one example of the oleophilization treatment method, the surface of fine particles is hydrophilized, and the hydrophilized surface is subjected to oleophilization treatment using a silane coupling agent such as tetraethoxysilane or hexamethyldisilazane. However, in this method, when the surface of the fine particles is not easily hydrophilized, the treatment with the silane coupling agent is difficult to perform.

In one method proposed to solve the foregoing problems, the surface of fine particles is coated with a metal oxide film of nanometer thickness. By coating the surface of the fine particles with the metal oxide film, the surface of the fine particles can be easily hydrophilized by, for example, plasma treatment. Moreover, the hydrophilized surface of the fine particles can be optionally subjected to oleophilization treatment with a coupling agent.

One promising method used to coat fine particles with metal oxide is an atomic layer deposition (ALD) method. For example, Non Patent Document 1 reports an example of a rotary-type atomic layer deposition method.

FIG. 7 is a schematic illustration of a metal oxide film formation apparatus in Non Patent Document 1. As illustrated, in the metal oxide film formation apparatus in Non Patent Document 1 (hereinafter referred to as a “conventional apparatus 100”), to-be-treated fine particles P′ to be coated with a metal oxide film are stored in a rotary drum 110 that is a container having fine holes, and the rotary drum 110 is placed in a vacuum container 120. The rotary drum 110 is rotatable using a rotary mechanism 130 connected to the rotary drum 110. An organometallic gas supply pipe 140 for supplying a raw material gas for the oxide thin film, an oxidizing gas supply pipe 150 for supplying an oxidizing gas for oxidizing the surface of the to-be-treated fine particles P′, and an inert gas supply pipe 160 for supplying an inert gas for cleaning the surface of the to-be-treated fine particles P′ are connected to the vacuum container 120. An evacuation pump (not shown) for evacuating the vacuum container 120 is provided at an exhaust port 121 thereof, and heating means 170 for heating inside the vacuum container 120 is provided therefor. A metal oxide film can thereby be formed.

Next, a description will be given of a method for forming a metal oxide film on the surface of the to-be-treated fine particles P′ using the conventional apparatus 100. First, the to-be-treated fine particles P′ are stored in the rotary drum 110 inside the vacuum container 120. While heated to 100° C. by the heating means 170, the rotary drum 110 is rotated about its horizontally disposed central axis by the rotary mechanism 130, and the evacuation pump is used to evacuate the inside of the vacuum container 120 through the exhaust port 121. Then the organometallic gas is supplied from the organometallic gas supply pipe 140 to the vacuum container 120. The to-be-treated fine particles P′ are thereby exposed to the organometallic gas, and molecules of the organometallic gas adsorb on the surface of the to-be-treated fine particles P′. Next, an inert gas is supplied from the inert gas supply pipe 160 to the vacuum container 120 to clean the vacuum container 120, and then water vapor serving as the oxidant (oxidizing gas) is supplied from the oxidizing gas supply pipe 150 to the vacuum container 120 to oxidize the surface of the to-be-treated fine particles P′, and a metal oxide film is thereby formed. Then an inert gas is supplied from the inert gas supply pipe 160 to the vacuum container 120 to clean the surface of the metal oxide film.

In the rotary-type atomic layer deposition method using the conventional apparatus 100, a cycle composed of the steps of supplying the gases is repeated a plurality of times according to the thickness of the metal oxide film to be formed on the surface of the to-be-treated fine particles P′, and the metal oxide film having a prescribed thickness can thereby be formed. Non-Patent Document 1 discloses an example in which acetaminophen particles are used as the to-be-treated fine particles P′ and a metal oxide film such as a titanium oxide film or an alumina film is formed on their surface.

### PRIOR ART DOCUMENT

### Non-Patent Document

Non Patent Document 1: T. O. Kääriäinen, International Journal of Pharmaceutics, VOL. 525, 2017, p. 160-p. 174

### SUMMARY OF THE INVENTION

### Problems to be Solved by the Invention

The reason why the conventional apparatus 100 is configured such that the to-be-treated fine particles P′ are stored in the rotary drum 110 having fine holes is to allow the organometallic gas supplied to the vacuum container 120 to be introduced into the rotary drum 110 and to prevent the to-be-treated fine particles P′ from scattering throughout the vacuum container 120. The reason that the rotary drum 110 is rotated using the rotary mechanism 130 is to stir the to-be-treated fine particles P′ to cause the organometallic gas molecules to efficiently adsorb on the surface of the to-be-treated fine particles P′. It is therefore possible to use the conventional apparatus 100 to form the metal oxide film on the surface of the to-be-treated fine particles P′ by the rotary-type atomic layer deposition method.

However, the rotary-type atomic layer deposition method has the following problems. In order to cause the organometallic gas to infiltrate through the fine holes of the rotary drum 110, a large amount of the raw material gas must be supplied. Also, the efficiency of utilization of the organometallic gas supplied is low. Another problem with the atomic layer deposition methods including the rotary-type atomic layer deposition method is that, since a high temperature of 100° C. or higher is necessary during deposition of atomic layers, it is difficult to form a metal oxide film on a powder material that cannot be treated at high temperature. Moreover, to-be-treated fine particles P′ of a specific powder material easily aggregate when stirred.

The present invention has been proposed in view of the problems of the above-described conventional technique, and it is an object to provide a metal oxide thin film formation apparatus and a metal oxide thin film formation method that can utilize a raw material gas with improved efficiency irrespective of temperature conditions and the type of powder material and can reliably form a metal oxide thin film on the surface of fine particles while preventing aggregation of the fine particles as needed.

### Means for Solving the Problems

A first mode of the present invention for solving the above-described problems is a metal oxide thin film formation apparatus for forming a metal oxide thin film on the surface of fine particles, the metal oxide thin film formation apparatus being characterized by comprising: a vacuum container to which evacuation means is connected; a treatment container that is disposed inside the vacuum container, has a cylindrical tubular shape, is rotatable about a central axis disposed to extend in a horizontal direction or incline in relation to the horizontal direction, and has an opening formed in one end face of the treatment container; oxidizing gas supplying means for supplying an oxidizing gas to the vacuum container; and organometallic gas supplying means for supplying an organometallic gas, the organometallic gas supplying means being inserted into the treatment container from the opening thereof, and further comprising control means for performing (1) an organometallic gas supplying step of supplying the organometallic gas using the organometallic gas supplying means to the treatment container into which fine particles are placed as a to-be-treated object, (2) a first gas evacuating step of evacuating gas inside the vacuum container using the evacuation means, (3) an oxidizing gas supplying step of supplying the oxidizing gas using the oxidizing gas supplying means to the vacuum container, and (4) a second gas evacuating step of evacuating gas inside the vacuum container using the evacuation means, the control means repeating the series of steps (1) to (4) a predetermined number of times according to a thickness of a metal oxide thin film to be formed on the surface of the fine particles.

A second mode of the present invention is a metal oxide thin film formation apparatus of the first mode, further comprising aggregation preventing means that is placed in the treatment container together with the fine particles, formed of a metal, a ceramic, or a resin, and stirred and mixed with the fine particles when the treatment container is rotated about the central axis, to thereby prevent aggregation.

A third mode of the present invention is a metal oxide thin film formation apparatus of the first or second mode, wherein the vacuum container has an opening formed in its side surface and connected to the evacuation means, and the relation S₁<S₂ holds, where S₁ is the area of the opening of the treatment container, and S₂ is the area of the opening of the vacuum container.

A fourth mode of the present invention is a metal oxide thin film formation apparatus of any one of the first through third modes, wherein the oxidizing gas contains one or a plurality of species selected from the group consisting of noble gases, radicals of noble gas components, hydrogen radicals, monoatomic hydrogen, oxygen radicals, monoatomic oxygen, and OH species.

A fifth mode of the present invention for solving the above-described problems is a metal oxide thin film formation method for forming a metal oxide thin film on the surface of fine particles, the method being characterized by using a metal oxide thin film formation apparatus including: a vacuum container to which evacuation means is connected; a treatment container that is disposed inside the vacuum container, has a cylindrical tubular shape, is rotatable about a central axis disposed to extend in a horizontal direction or incline in relation to the horizontal direction, and has an opening formed in one end face of the treatment container; oxidizing gas supplying means for supplying an oxidizing gas to the vacuum container; organometallic gas supplying means for supplying an organometallic gas, the organometallic gas supplying means being inserted into the treatment container from the opening thereof; and control means for performing (1) an organometallic gas supplying step of supplying the organometallic gas using the organometallic gas supplying means to the treatment container into which fine particles are placed as a to-be-treated object, (2) a first gas evacuating step of evacuating gas inside the vacuum container using the evacuation means, (3) an oxidizing gas supplying step of supplying the oxidizing gas using the oxidizing gas supplying means to the vacuum container, and (4) a second gas evacuating step of evacuating gas inside the vacuum container using the evacuation means, the series of steps (1) to (4) being repeated a predetermined number of times according to a thickness of a metal oxide thin film to be formed on the surface of the fine particles.

A sixth mode of the present invention is a metal oxide thin film formation method of the fifth mode, wherein the metal oxide thin film formation apparatus further includes aggregation preventing means that is placed in the treatment container together with the fine particles and formed of a metal, a ceramic, or a resin, and in each of the steps (1) to (4), the treatment container is rotated about the central axis, so that the aggregation preventing means and the fine particles are stirred and mixed together to prevent aggregation.

A seventh mode of the present invention is a metal oxide thin film formation method of the fifth or sixth mode, wherein the step (1) and the step (3) are repeated while gas inside the vacuum container is always exhausted by the evacuation means.

An eighth mode of the present invention is a metal oxide thin film formation method of any one of the fifth to seventh modes, wherein the oxidizing gas supplied by the oxidizing gas supplying means contains one or a plurality of species selected from the group consisting of noble gases, radicals of noble gas components, hydrogen radicals, monoatomic hydrogen, oxygen radicals, monoatomic oxygen, and OH species, and in the step (3), through supply of the oxidizing gas, organometallic gas molecules adsorbed on the surface of the fine particles or on the surface of the metal oxide thin film formed on the surface of the fine particles are oxidized so as to form a metal oxide thin film, and OH groups are formed on the surface of the metal oxide thin film so as to hydrophilize the surface of the metal oxide thin film.

### Effects of the Invention

The present invention can provide a metal oxide thin film formation apparatus and a metal oxide thin film formation method that can utilize a raw material gas with improved efficiency irrespective of temperature conditions and the type of powder material and can reliably form a metal oxide thin film on the surface of fine particles while preventing aggregation of the fine particles as needed.

### BRIEF DESCRIPTION OF THE DRAWINGS

FIG. 1

A schematic illustration of a metal oxide thin film formation apparatus according to an embodiment of the present invention.

FIG. 2

A schematic illustration of an oxidizing gas supply unit of the metal oxide thin film formation apparatus.

FIG. 3

A schematic illustration of a reaction container of a metal oxide thin film formation apparatus used in Example 1.

FIG. 4

A TEM image of a fine particle produced in Example 1.

FIG. 5

A schematic illustration of a reaction container of a metal oxide thin film formation apparatus used in Example 2.

FIG. 6

A TEM image of a fine particle produced in Example 2.

FIG. 7

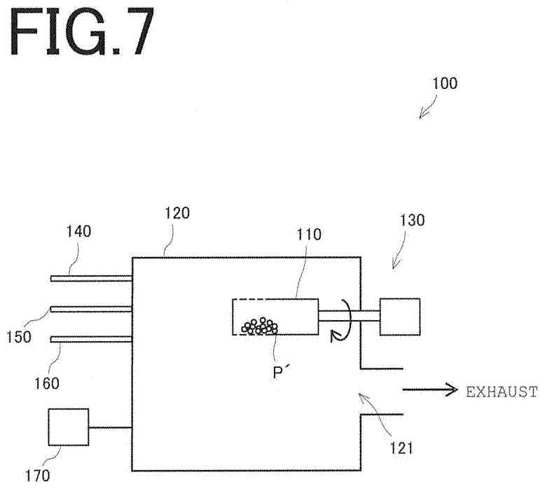

A schematic illustration of a metal oxide film formation apparatus in Non Patent Document 1.

### MODES FOR CARRYING OUT THE INVENTION

### (Metal Oxide Thin Film Formation Apparatus)

A metal oxide thin film formation apparatus according to an embodiment of the present invention will be described.

The metal oxide thin film formation apparatus of the present invention is an apparatus that uses a low-temperature atomic layer deposition method as a method for coating a powder material with metal oxide, can utilize a raw material gas with improved efficiency irrespective of temperature conditions and the type of powder material, and can reliably form a metal oxide thin film on the surface of fine particles while aggregation of the fine particles is prevented as needed.

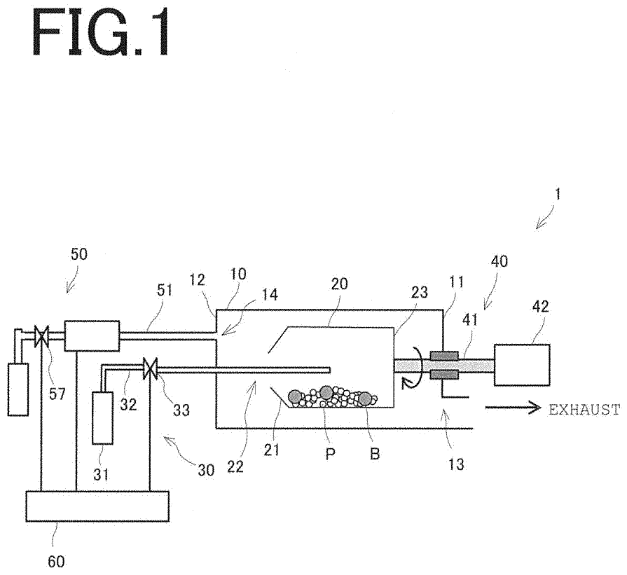

FIG. 1 is a schematic illustration of a metal oxide thin film formation apparatus that describes one embodiment of the present invention. As illustrated, in the metal oxide thin film formation apparatus 1, a treatment container 20 having a cylindrical tubular shape is disposed inside a vacuum container 10 that can be evacuated. The treatment container 20 has an inclination on one end face with respect to the horizontal direction, is disposed such that the rotation axis of the treatment container 20 is horizontal, and used to perform treatment for coating a powder material (to-be-treated object) with metal oxide within the treatment container 20. The treatment container 20 is configured such that an organometallic gas can be supplied from an organometallic gas supply unit 30 through an opening 22 provided on one end face (first end face 21) and is connected to a rotating unit 40 so as to be rotatable. In the present embodiment, the treatment container 20 is rotatable about a central axis (rotation center) disposed to extend in the horizontal direction. However, this structure is not a limitation, and any other structure may be used so long as the to-be-treated object can be coated with metal oxide within the treatment container 20. For example, the central axis disposed to incline in relation to the horizontal direction may be used as the rotation center. Unillustrated evacuation means is connected to one end face (first end face 11), with respect to the horizontal direction, of the vacuum container 10, and an oxidizing gas supply unit 50 is connected to the other end face (second end face 12) through a glass pipe 51. The organometallic gas supply unit 30 and the oxidizing gas supply unit 50 are each electrically connected to a controller 60, so that supply timings of various gases, their supply amounts, etc. can be controlled.

Next, the details of components of the metal oxide thin film formation apparatus 1 will be described.

No particular limitation is imposed on the powder material (to-be-treated object). The powder material is fine particles P having a diameter on the order of nanometers or micrometers. Examples of the powder material include, in addition to metal powder materials, powder materials composed of fine particles with surfaces which resist oxidation and on which a coating is not easily formed by conventional methods (such as the method described in Non-Patent Document 1) (e.g., carbon powder) and powder materials whose characteristics are changed by hydrophilization treatment or oleophilization treatment (e.g., resin powder). These powder materials cannot be subjected to treatment at high temperature (for example, 100° C. or higher). No particular limitation is imposed on the diameter of the fine particles P that can be subjected to coating treatment in the metal oxide thin film formation apparatus 1, so long as the fine particles P have a diameter on the order of nanometers or micrometers. In the present embodiment, the fine particles P used are zinc sulfide (ZnS) particles having a diameter of 10 μm to 20 μm.

No particular limitation is imposed on the material, shape, size, etc. of the vacuum container 10, so long as it can maintain a vacuum state and has properties such as strength, heat resistance, corrosion resistance, and workability that are commonly required for containers. A first opening 13 used as an exhaust port is provided on the first end face 11, with respect to the horizontal direction, of the vacuum container 10, and the unillustrated evacuation means is connected to the first opening 13. The evacuation means is a vacuum pump for evacuating the vacuum container 10, and the type of vacuum pump is appropriately selected according to the required degree of vacuum. For example, an oil rotary pump, a dry pump, a diffusion pump, a cryopump, a turbo molecular pump, a sputter ion pump, etc. may be used. A second opening 14 used as a supply port is provided on the second end face 12, and the oxidizing gas supply unit 50 is connected to the second opening 14 through the glass pipe 51 described later. The oxidizing gas can be supplied to the inner treatment container 20 using the oxidizing gas supply unit 50.

The treatment container 20 has a cylindrical tubular shape and has the inclination on the first end face 21 with respect to the horizontal direction, and the opening 22 which is open toward the interior of the vacuum container 10 is provided at the center of the first end face 21. A powder material (fine particles P) to be subjected to the coating treatment with metal oxide and balls B used as aggregation preventing means for preventing aggregation of the fine particles P are placed inside the treatment container 20. The treatment container 20 is formed of preferably a material having at least electrical conductivity and particularly preferably a metal. The reason for this is to prevent the fine particles P from electrostatically adhering to the treatment container 20.

In the present embodiment, to coat the fine particles P with metal oxide, it is necessary to evacuate the treatment container 20 disposed inside the vacuum container 10. In view of the above, the opening 22 is formed in the first end face 21 of the treatment container 20, the treatment container 20 together with the vacuum container 10 can be evacuated by the evacuation means through the opening 22. When the coating treatment of the fine particles P is performed, the organometallic gas used as the raw material gas for the oxide thin film can be supplied to the inside of the treatment container 20 using the organometallic gas supply unit 30 through the opening 22.

Let the area of the opening 22 be S₁, and the area of the first opening 13 of the vacuum container 10 be S₂. The opening 22 is formed such that the area S₁ is smaller than the area S₂ of the first opening 13 of the vacuum container 10, i.e., S₁ and S₂ satisfy the relation S₁<S₂. By virtue of this structure, the internal pressure P₁ of the treatment container 20 is higher than the internal pressure P₂ of the vacuum container 10, so that the organometallic gas can be efficiently supplied to the fine particles P placed inside the treatment container 20. Specifically, when the coating treatment of the fine particles P is performed, the areas S₁ and S₂ are proportional to respective exhaust speeds. The products of the exhaust speeds and the internal pressures P₁ and P₂ are flow rates, and the relation S₁×P₁=S₂×P₂ holds. Therefore, the internal pressure P₁ of the treatment container 20 is S₂/S₁ times the internal pressure P₂ of the vacuum container 10. Since the relation S₁<S₂ holds as described above, the partial pressure of the organometallic gas can be increased, and the organometallic gas can be efficiently supplied to the treatment container 20, so that the efficiency of utilization of the organometallic gas can be increased.

In the treatment container 20, the rotating unit 40 is connected to the other end face (second end face 23) of the treatment container 20, so that the treatment container 20 can be rotated. During coating treatment, the fine particles P and the balls B are placed in the treatment container 20, and the treatment container 20 is rotated to stir and mix the fine particles P and the balls B. Therefore, the treatment container 20 has a cylindrical tubular shape suitable for stirring and mixing. The shape of the treatment container 20 is not limited to the cylindrical tubular shape having a curved inner wall surface so long as corners, protrusions, etc. that inhibit stirring and mixing of the fine particles P and the balls B are not present on the inner wall surface. For example, the treatment container 20 may have an elliptical tubular shape, a polygonal tubular shape, etc.

No particular limitation is imposed on the structure of the treatment container 20, so long as the treatment container 20 has a structure which prevents the fine particles P and the balls B placed therein from flying to the interior of the vacuum container 10 through the opening 22 when the treatment container 20 is rotated. Preferably, for example, the treatment container 20 has a structure in which an inclination is provided on the first end face 21 with respect to the horizontal direction. In particular, it is preferable that the treatment container 20 has a structure in which the first end face 21 of the treatment container 20 has a reverse conical shape or a structure in which the first end face 21 is taped toward the center from two directions.

In the present embodiment, the first end face 21 of the treatment container 20 is formed by a sloping surface protruding toward one inner wall, with respect to the horizontal direction, of the vacuum container 10. Therefore, when the treatment container 20 is rotated, the fine particles P and the balls B impinge on the sloping surface, bounce back, and return to the treatment container 20. This can prevent the fine particles P and the balls B from flying to the interior of the vacuum container 10. The bouncing back balls B accelerate the stirring and mixing of the fine particles P. This is advantageous in terms of adsorption of the organometallic gas onto the surface of the fine particles P and in terms of prevention of aggregation of the fine particles P.

The balls B, serving as the aggregation preventing means, are mixed with the fine particles P stirred by the rotation of the treatment container 20, whereby aggregation of the fine particles P is prevented. No particular limitation is imposed on the balls B so long as they have a shape that allows them to be easily mixed with the fine particles P. Preferably, the balls B are spherical. It is, however, unnecessary that the balls B be perfect spheres, and it is only necessary that the balls B have a shape with no corners, protrusions, etc. that impede stirring and mixing. The balls B are allowed to have corners, protrusions, distortions, etc. so long as they do not impede stirring and mixing of the fine particles P.

It is only necessary that the surface of the balls B that comes into contact with the fine particles P be formed of a material that does not react with the fine particles P, and the balls B used may be formed of, for example, a metal, a ceramic, or a resin. Alternatively, only the surface that comes into contact with the fine particles P may be coated with a metal, a ceramic, or a resin. No particular limitation is imposed on the material of the core of the balls B, so long as they function as the aggregation preventing means. To prevent electrostatic adhesion of the balls B to the fine particles P, it is preferable that the balls B used are formed of a metal or only their surface is coated with a metal. The size of the balls B is appropriately determined according to the to-be-treated object. In the present embodiment, the balls B used are stainless steel balls having a diameter of about 3 mm to about 5 mm.

When, for example, the fine particles P used are unlikely to aggregate during stirring and mixing, it is not always necessary to use the balls B. Whether the balls B are used may be determined according to the circumstances. The aggregation preventing means is not limited to the balls B. Other aggregation preventing means such as stirring means, e.g., stirring blades, may be disposed inside the treatment container 20.

The organometallic gas used as the raw material gas is supplied from the organometallic gas supply unit 30 to the treatment container 20. The organometallic gas supply unit 30 includes a raw material gas tank 31 filled with the raw material gas, a supply pipe 32 used as a supply channel of the raw material gas, and a flow rate control valve 33 for opening and closing the supply pipe 32. The raw material gas tank 31 is connected to a proximal end portion of the supply pipe 32, and the supply pipe 32 is fixed with its distal end portion inserted into the treatment container 20 through the opening 22, so that the raw material gas can be supplied to the treatment container 20. By introducing the raw material gas with the distal end portion of the supply pipe 32 inserted into the treatment container 20, the partial pressure of the raw material gas on the surface of the fine particles P in the treatment container 20 can be effectively increased, and the coating treatment can be performed using a small supply amount of the raw material gas. The supply amount of the raw material gas is controlled by opening and closing the flow rate control valve 33.

The raw material gas is an organometallic gas that may be appropriately selected according to the type of metal oxide used for the coating treatment on the surface of the fine particles P. For example, when a titanium oxide film is formed on the surface of the fine particles P, tetrakis(dimethylamino)titanium, for example, may be used as the organometallic gas. When an alumina film is formed, trimethylaluminum, for example, may be used. When a silica film is formed, trimethylaminosilane, for example, may be used. When a zirconium oxide film is formed, tetrakis(ethylmethylamino)zirconium, for example, may be used. When a hafnium oxide film is formed, tetrakis(ethylmethylamino)hafnium, for example, may be used. In the present embodiment, a titanium oxide film or an alumina film is formed on the surface of the fine particles P.

The rotating unit 40 is connected to the second end face 23 of the treatment container 20. The rotating unit 40 can rotate the treatment container 20 about a shaft 41 (rotation center) disposed to extend in the horizontal direction. Specifically, the shaft 41 is connected to a rotation introduction unit 42 such as a motor, and the shaft 41 is driven to rotate by the rotation introduction unit 42. The treatment container 20 can be rotated together with the rotation of the shaft 41. No particular limitation is imposed on the structure of the rotating unit 40 so long as it can rotate the treatment container 20 in the manner described above.

The oxidizing gas is supplied from the oxidizing gas supply unit 50 to the vacuum container 10. In an example described in the present embodiment, the oxidizing gas supply unit 50 is a plasma gas generator. The plasma gas generator uses argon gas, helium gas, or a gas mixture thereof (such a gas is hereinafter referred to as a noble gas). The noble gas is humidified and turned to plasma by a high-frequency magnetic field or a high-frequency electric field, and activated plasma gas is thereby generated. The plasma gas is an example of the oxidizing gas in the present embodiment. When the plasma of the gas (humidified gas) obtained by humidifying the noble gas is used as the oxidizing gas, the oxidizing gas contains one or a plurality of species selected from the group consisting of noble gases (e.g., argon gas), radicals of noble gas components (e.g., argon radicals), hydrogen radicals, monatomic hydrogen, oxygen radicals, monatomic oxygen, and OH species (e.g., OH radicals).

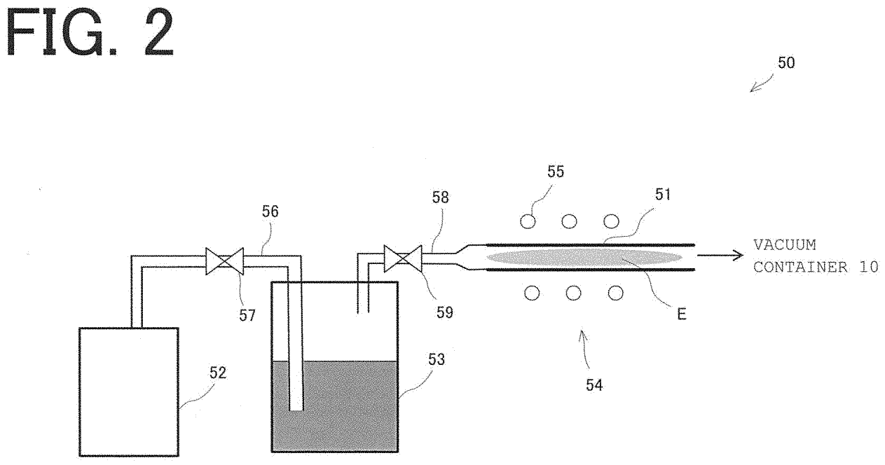

FIG. 2 is a schematic illustration of the oxidizing gas supply unit of the metal oxide thin film formation apparatus. As illustrated, the oxidizing gas supply unit 50 includes a noble gas storage tank 52, a water bubbler 53, and a plasma generator 54. The plasma generator 54 includes the glass pipe 51 and an induction coil 55 disposed around the glass pipe 51 and generates plasma in a region E inside the glass pipe 51. Water is stored inside the water bubbler 53, and the noble gas is introduced into the water from the noble gas storage tank 52 and caused to pass through the water. The noble gas is thereby humidified, and a humidified gas, which is a gas mixture of the noble gas and water vapor, is obtained. In the oxidizing gas supply unit 50, the noble gas is supplied to the water bubbler 53 through a supply pipe 56, and the flow rate of the noble gas is controlled by opening and closing a flow rate control valve 57. The humidified gas is supplied to the glass pipe 51 through a supply pipe 58 connected to the glass pipe 51, and the flow rate of the humidified gas is controlled by opening and closing a flow rate control valve 59.

In the above oxidizing gas supply unit 50, the humidified gas generated in the water bubbler 53 is introduced into the glass pipe 51 and caused to pass through the region E in which plasma is generated by the high-frequency magnetic field applied by the induction coil 55, and the plasma gas (oxidizing gas) composed of the activated humidified gas is thereby generated and introduced into the vacuum container 10. In the present embodiment, the high-frequency energy applied by the induction coil 55 is 100 W, and the frequency is 13.56 MHz.

As shown in FIG. 1, the flow rate control valve 33 of the organometallic gas supply unit 30 and the flow rate control valves 57 and 59 of the oxidizing gas supply unit 50 (see FIG. 2; however, the connection between the flow rate control valve 59 and the controller 60 is not illustrated.) are electrically connected to the controller 60. By controlling the opening-closing timings and opening degrees of the flow rate control valve 33 and the flow rate control valves 57 and 59, the supply timings of the gases, their supply amounts, etc. can be controlled. The controller 60 appropriately determines the total supply amounts of the gasses according to the thickness of the metal oxide thin film. When the treatment described later is repeated, the supply amounts of the gasses necessary for one treatment procedure are computed from the determined total supply amounts, and the opening degrees of the flow rate control valves 33, 57, and 59 are controlled according to the computed amounts.

### (Metal Oxide Thin Film Formation Method)

Next, a metal oxide thin film formation method according to an embodiment of the present invention will be described.

In the present embodiment, a low-temperature atomic layer deposition method is used as a method for coating the surface of the fine particles P with metal oxide. In this method, a metal oxide thin film is formed on a solid sample at low temperature (e.g., room temperature). This metal oxide thin film formation method includes: a preparation step of placing the fine particles P and the balls B in the treatment container 20 and optionally supplying the oxidizing gas to the vacuum container 10 to hydrophilize the surface of the fine particles P; (1) an organometallic gas supplying step of supplying from the organometallic gas supply unit 30 to the treatment container 20; (2) a first gas evacuating step of evacuating gas inside the vacuum container 10 using the unillustrated evacuation means; (3) an oxidizing gas supplying step of supplying the oxidizing gas from the oxidizing gas supply unit 50 to the vacuum container 10; and (4) a second gas evacuating step of evacuating gas inside the vacuum container 10 using the evacuation means. Using the metal oxide thin film formation apparatus 1, the series of steps (1) to (4) is repeated a predetermined number of times according to the thickness of the metal oxide thin film to be formed on the surface of the fine particles P.

In the case where the fine particles P to be coated with the metal oxide are those which allow adsorption of the organometallic gas to the surface of the fine particles P to form a monolayer film of the organometallic gas molecules on the surface without hydrophilizing the surface, the hydrophilization treatment in the preparation step is unnecessary. Whether the hydrophilization treatment is necessary can be judged appropriately according to the material of the fine particles P used.

In the present embodiment, continuous evacuation is performed to omit (2) the first gas evacuating step and (4) the second gas evacuating step, and (1) the organometallic gas supplying step and (3) the oxidizing gas supplying step are repeated, but this is not a limitation. Instead of the continuous evacuation, the series of steps (1) to (4) may be repeated.

Specifically, in the preparation step, the fine particles P together with the balls B are placed in the treatment container 20, and the rotating unit 40 is activated to rotate the treatment container 20 at a speed of several revolutions per minute. In this case, the treatment container 20 is rotated intermittently or continuously as needed, and the evacuation means is activated to continuously evacuate the vacuum container 10. Next, the flow rate control valve 57 is controlled by the controller 60 so as to introduce the noble gas into the water bubbler 53 through the supply pipe 56, and water vapor-containing noble gas (a gas mixture of the noble gas and water vapor) is thereby produced. Then, the flow rate control valve 59 is controlled by the controller 60 so as to introduce the gas mixture into the glass pipe 51 through the supply pipe 58. At that time, a high-frequency magnetic field is applied from the induction coil 55 disposed around the outer circumference of the glass pipe 51 to generate plasma inside the glass pipe 51. A humidified gas (plasma gas) excited by the plasma is thereby generated and introduced into the vacuum container 10. When the plasma gas is introduced into the vacuum container 10, as a result of adsorption of OH radicals in the plasma gas, the surface of the fine particles P is oxidized and hydrophilized, and this allows adsorption of organometallic gas molecules in (1) the organometallic gas supplying step to be performed next.

Next, in (1) the organometallic gas supplying step, the flow rate control valve 33 is controlled by the controller 60 so as to supply the organometallic gas to the treatment container 20 through the supply pipe 32. When the organometallic gas is supplied to the treatment container 20, the organometallic gas reacts with the OH groups on the surface of the fine particles P and adsorbs on the surface. The adsorption ends when organometallic gas molecules cover the entire surface of the fine particles P, whereby a monolayer film of the organometallic gas molecules is formed on the surface.

Next, in (3) the oxidizing gas supplying step, as in the preparation step, the oxidizing gas supply unit 50 is used to generate a humidified gas (plasma gas), and the humidified gas is introduced into the vacuum container 10. When the plasma gas is introduced into the vacuum container 10, OH radicals, oxygen radicals, etc. in the plasma gas cause oxidation of the monolayer (equivalent to one molecule thickness) film of the organometallic gas molecules on the surface of the fine particles P, whereby a thin metal oxide film is formed. The adsorption of the OH radicals causes the surface of the fine particles P to be hydrophilized, and this allows adsorption of organometallic gas particles in (1) the organometallic gas supplying step to be performed next.

In the preparation step and (3) the oxidizing gas supplying step, the organometallic gas is not supplied to the treatment container 20, and the internal pressure P₁ of the treatment container 20 is nearly the same as the internal pressure P₂ of the vacuum container 10 (P₁≅P₂), so that the plasma gas supplied to the vacuum container 10 is supplied also to the treatment container 20. As a result, in the preparation step, the surface of the fine particles P can thereby be hydrophilized, and in (3) the oxidizing gas supplying step, a thin metal oxide film can be formed on the surface of the fine particles P, and the surface of the fine particles P can be hydrophilized.

(1) A cycle composed of the organometallic gas supplying step and (3) the oxidizing gas supplying step is repeated, whereby a metal oxide thin film having a thickness proportional to the number of repetitions of the cycle is formed on the surface of the fine particles P.

In the present embodiment, in the course of processing for obtaining a material in which the fine particles P used as a raw material are mixed with and dispersed in a liquid, a plastic, or a resin, a metal oxide coating can be easily formed on the surface of the fine particles P, and the wettability, hydrophobicity, etc. of the surface can be easily controlled.

### EXAMPLES

### Example 1

In Example 1, a metal oxide thin film formation apparatus described later was used to coat zinc sulfide (ZnS) particles (hereinafter referred to as ZnS particles) used as the powder material with an aluminum oxide (alumina: Al₂O₃) film of 5 nm. In the metal oxide thin film formation apparatus, stainless steel balls (50 balls) having a diameter of about 3 mm to about 5 mm and serving as the aggregation preventing means were stored together with the ZnS particles. The ZnS particles have a diameter of 10 μm to 20 μm, and the organometallic gas for alumina is trimethylaluminum ((CH₃)₃Al).

In (1) the organometallic gas supplying step described above, the supply amount of trimethylaluminum is 150,000 Langmuir (1 Langmuir is an exposure amount corresponding to 1.33×10⁻⁴ Pa×1 second). In (3) the oxidizing gas supplying step described above, the plasma gas used was produced by bubbling pure water having a temperature of 50° C. with argon at a flow rate of 15 sccm and exciting the argon at an RF electric power of 100 W. The plasma was generated by the induction coil, and the RF frequency was 13.56 MHz. The plasma contains, in addition to the argon gas, argon radicals, hydrogen radicals, monoatomic hydrogen, oxygen radicals, monoatomic oxygen, and OH species. The supply time of the plasma gas was 120 seconds. In (1) the organometallic gas supplying step and (3) the oxidizing gas supplying step, 100 gas supply cycles were performed.

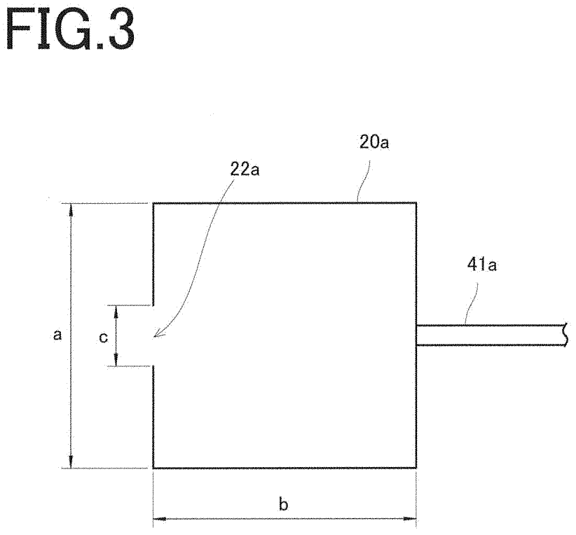

FIG. 3 is a schematic illustration of a reaction container of the metal oxide thin film formation apparatus used in Example 1. In Example 1, the treatment container 20 of the metal oxide thin film formation apparatus 1 in FIG. 1 was replaced by the treatment container 20a shown in FIG. 3. As shown in FIG. 3, the treatment container 20a of the metal oxide thin film formation apparatus in Example 1 is made of SUS304, has a cylindrical tubular shape with a radial length a of 71 mm and an axial length b of 57 mm, and has a circular opening 22a with a diameter c of 21.75 mm. The treatment container 20a is connected to a shaft 41a that can support and rotate the treatment container 20a.

The treatment container 20a is made of SUS304. When a treatment container 20b made of glass is used as in Example 2 described later, its inner surface is coated with aluminum in order to prevent the surface from being electrically charged.

In Example 1, a cycle composed of the preparation step, (1) the organometallic gas supplying step, and (3) the oxidizing gas supplying step was repeated 400 times to form an alumina film having a prescribed thickness on the surface of the ZnS particles. In the preparation step, 24 g of the ZnS particles were stored in the treatment container 20a, and 50 stainless steel balls were stored in the treatment container 20a. Then the treatment container 20a was rotated at a speed of 13.5 revolution per minute for 1 hour. Then, TEM images of the ZnS particles obtained were captured by using a transmission electron microscope (SEM: Scanning Electron Microscope).

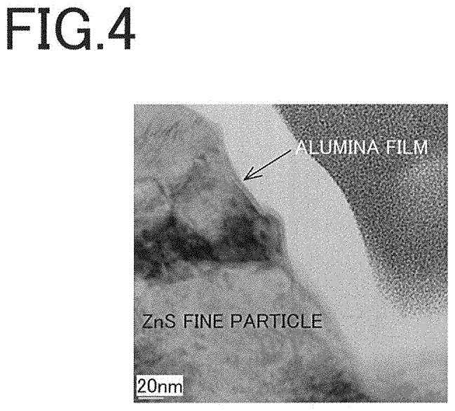

FIG. 4 is a TEM image of a fine particle produced in Example 1. As can be seen from the image, the surface of a ZnS fine particle can be coated with an alumina film. The observation was performed at several points on the surface of the ZnS fine particle, and the alumina film was found to be formed uniformly.

In Example 1, the inner diameter of the opening 22a of the treatment container 20a is 21.75 mm, and the inner diameter of the exhaust port (the first opening 13) of the vacuum container 10 is 100 mm. Therefore, from the above-described flow speed relational expression (S₁×P₁=S₂×P₂). the internal pressure of the treatment container 20a becomes 21.1 times the internal pressure of the vacuum container 10. Specifically, when the distal end portion of the supply pipe 32 of the organometallic gas supply unit 30 is inserted into the opening 22a and the organometallic gas is supplied to the treatment container 20a, the partial pressure of the organometallic gas become 6.9 times that when no organometallic gas is supplied. Therefore, the supply amount of the organometallic gas can be reduced, and the organometallic gas used as the raw material gas can be utilized effectively.

### Example 2

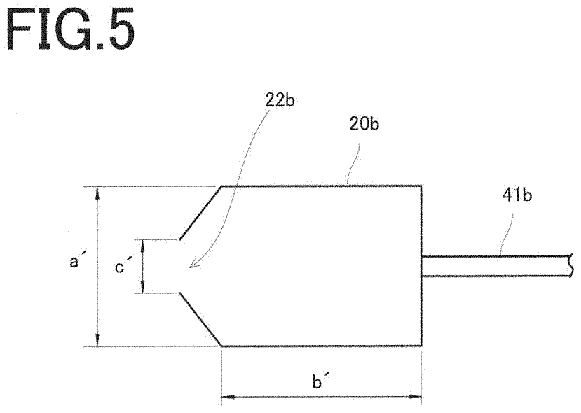

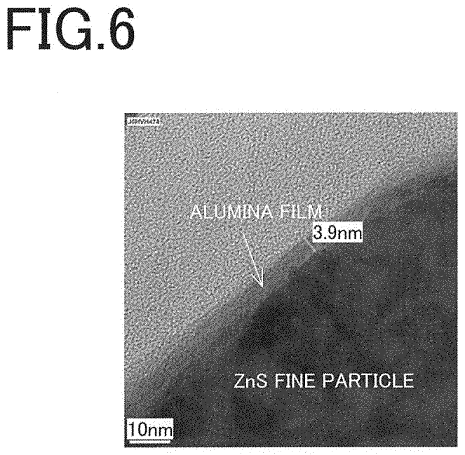

FIG. 5 is a schematic illustration of a reaction container of a metal oxide thin film formation apparatus used in Example 2. In Example 2, the metal oxide thin film formation apparatus used is the same as that in Example 1 except that the treatment container 20b and a shaft 41b are used. Using this metal oxide thin film formation apparatus, an alumina film was formed on the surface of ZnS particles, and a transmission electron microscope was used to take TEM images of the ZnS particles. FIG. 6 is a TEM image of a fine particle produced in Example 2. As can be seen from the image, in Example 2, as in Example 1, the surface of the ZnS fine particle can be coated with the alumina film.

The treatment container 20b is made of glass, has a cylindrical tubular shape with a radial length a′ of 65 mm and an axial length b′ of 50 mm, and has a circular opening 22b with a diameter c′ of 32 mm. In contrast to the treatment container 20a in Example 1, the treatment container 20b has an inclination provided on one end face, with respect to the horizontal direction, on the opening 22b side.

### Example 3

An alumina film was formed on the surface of nickel (Ni) particles using the metal oxide thin film formation apparatus in the same manner as in Example 2 except that 50.00 g of the Ni particles were used as the powder material. Although the amount of recovered ZnS particles with the alumina film formed on their surface in Example 1 was 45.77 g, the amount of recovered Ni particles with the alumina film formed on their surface in Example 3 was increased to 48.48 g. By using the treatment container 20b having the inclination on one end face, with respect to the horizontal direction, on the opening 22b side, the stainless steel balls impinging on the inclination bounce back, and the stirring and mixing of the Ni particles is thereby accelerated. This is found to be advantageous in terms of adsorption of trimethylaluminum gas onto the surface of the Ni particles and in terms of prevention of aggregation of the Ni particles.

### Other Embodiments

As described above, the metal oxide thin film formation apparatus of the present invention includes the vacuum container, the treatment container, the organometallic gas supply unit, the rotating unit, the evacuation means, the oxidizing gas supply unit, and the controller, but this structure is not a limitation, and the apparatus may include additional components as needed. Examples of the additional components include: a carrier gas supply unit for suppling a carrier gas composed of an inert gas to the vacuum container as needed; and a heating unit for heating the interior of the treatment container. When the carrier gas supply unit is provided, the organometallic gas in the vacuum container can be carried away by the carrier gas and exhausted in (2) the first gas evacuating step and (4) the second gas evacuating step. When the heating unit is provided, an oxide thin film can be formed by high-temperature treatment performed in the treatment container even when the organometallic gas used does not easily react at room temperature.

In the metal oxide thin film formation apparatus of the present invention, the plasma gas generator is used as the oxidizing gas supply unit, but this is not a limitation. Any other oxidizing gas supply unit may be used so long as it can produce an oxidizing gas and introduce it into the vacuum container. In the present invention, the noble gas is humidified in the plasma gas generator. The gas mixture of the humidified noble gas and water vapor is turned to plasma, and the plasma gas generated is used, but this is not a limitation. For example, an ozone gas generator may be used. The oxidizing gas in the ozone gas generator contains ozone gas.

The oxidizing gas supply unit is connected to the vacuum container through the glass pipe and supplies the oxidizing gas to the vacuum container, but this structure is not a limitation. For example, the distal end portion of the glass pipe of the oxidizing gas supply unit may be inserted into the treatment container through the opening so as to introduce the oxidizing gas into the treatment container. In this case, the glass pipe may optionally have a bent portion at an appropriate position so that the distal end portion of the glass pipe can be easily introduced into the treatment container, or the vertical position of the treatment container within the vacuum container may be changed. When the oxidizing gas is introduced into the treatment container, the internal pressure of the treatment container 20a becomes several times the internal pressure of the vacuum container 10 according to the flow speed relation (S₁×P₁=S₂×P₂) described above, so that the hydrophilization treatment on the powder material can be easily performed using a small supply amount of the oxidizing gas.

### INDUSTRIAL APPLICABILITY

The present invention is preferably used in the field of production of inks, water soluble pastes, etc. that use metal powder materials.

### DESCRIPTION OF REFERENCE NUMERALS

1: metal oxide thin film formation apparatus
10, 120: vacuum container
11, 21: first end face
12, 23: second end face
13: first opening
14: second opening
20, 20a, 20b: treatment container
22, 22a, 22b: opening
30: organometallic gas supply unit
31: raw material gas tank
32, 56, 58: supply pipe
33, 57, 59: flow rate control valve
40: rotating unit
41, 41a, 41b: shaft
42: rotation introduction unit
50: oxidizing gas supply unit
51: glass pipe
52: noble gas storage tank
53: water bubbler
54: plasma generator
55: induction coil
60: controller
100: conventional apparatus
110: rotary drum
121: exhaust port
130: rotary mechanism
140: organometallic gas supply pipe
150: oxidizing gas supply pipe
160: inert gas supply pipe
170: heating means
B: ball
E: region
P: fine particle
P′: to-be-treated fine particle

1. A metal oxide thin film formation apparatus for forming a metal oxide thin film on the surface of fine particles, the metal oxide thin film formation apparatus comprising:
a vacuum container to which evacuation means is connected;
a treatment container that is disposed inside the vacuum container, has a cylindrical tubular shape, is rotatable about a central axis disposed to extend in a horizontal direction or incline in relation to the horizontal direction, and has an opening formed in one end face of the treatment container;
oxidizing gas supplying means for supplying an oxidizing gas to the vacuum container; and
organometallic gas supplying means for supplying an organometallic gas, the organometallic gas supplying means being inserted into the treatment container from the opening thereof, and
further comprising control means for performing
(1) an organometallic gas supplying step of supplying the organometallic gas using the organometallic gas supplying means to the treatment container into which fine particles are placed as a to-be-treated object,
(2) a first gas evacuating step of evacuating gas inside the vacuum container using the evacuation means,
(3) an oxidizing gas supplying step of supplying the oxidizing gas using the oxidizing gas supplying means to the vacuum container, and
(4) a second gas evacuating step of evacuating gas inside the vacuum container using the evacuation means,
the control means repeating the series of steps (1) to (4) a predetermined number of times according to a thickness of a metal oxide thin film to be formed on the surface of the fine particles.

2. The metal oxide thin film formation apparatus according to claim 1, further comprising aggregation preventing means that is placed in the treatment container together with the fine particles, formed of a metal, a ceramic, or a resin, and stirred and mixed with the fine particles when the treatment container is rotated about the central axis, to thereby prevent aggregation.

3. The metal oxide thin film formation apparatus according to claim 1, wherein
the vacuum container has an opening formed in a side surface thereof and connected to the evacuation means, and
the relation S₁<S₂ holds, where S₁ is the area of the opening of the treatment container, and S₂ is the area of the opening of the vacuum container.

4. The metal oxide thin film formation apparatus according to claim 1, wherein
the oxidizing gas contains one or a plurality of species selected from the group consisting of noble gases, radicals of noble gas components, hydrogen radicals, monoatomic hydrogen, oxygen radicals, monoatomic oxygen, and OH species.

5. A metal oxide thin film formation method for forming a metal oxide thin film on the surface of fine particles, the method using a metal oxide thin film formation apparatus including:
a vacuum container to which evacuation means is connected;
a treatment container that is disposed inside the vacuum container, has a cylindrical tubular shape, is rotatable about a central axis disposed to extend in a horizontal direction or incline in relation to the horizontal direction, and has an opening formed in one end face of the treatment container;
oxidizing gas supplying means for supplying an oxidizing gas to the vacuum container;
organometallic gas supplying means for supplying an organometallic gas, the organometallic gas supplying means being inserted into the treatment container from the opening thereof; and
control means for performing
(1) an organometallic gas supplying step of supplying the organometallic gas using the organometallic gas supplying means to the treatment container into which fine particles are placed as a to-be-treated object,
(2) a first gas evacuating step of evacuating gas inside the vacuum container using the evacuation means,
(3) an oxidizing gas supplying step of supplying the oxidizing gas using the oxidizing gas supplying means to the vacuum container, and
(4) a second gas evacuating step of evacuating gas inside the vacuum container using the evacuation means,
the series of steps (1) to (4) being repeated a predetermined number of times according to a thickness of a metal oxide thin film to be formed on the surface of the fine particles.

6. The metal oxide thin film formation method according to claim 5, wherein
the metal oxide thin film formation apparatus further includes aggregation preventing means that is placed in the treatment container together with the fine particles and formed of a metal, a ceramic, or a resin, and
in each of the steps (1) to (4), the treatment container is rotated about the central axis, so that the aggregation preventing means and the fine particles are stirred and mixed together to prevent aggregation.

7. The metal oxide thin film formation method according to claim 5, wherein the step (1) and the step (3) are repeated while gas inside the vacuum container is always exhausted by the evacuation means.

8. The metal oxide thin film formation method according to claim 5, wherein
the oxidizing gas supplied by the oxidizing gas supplying means contains one or a plurality of species selected from the group consisting of noble gases, radicals of noble gas components, hydrogen radicals, monoatomic hydrogen, oxygen radicals, monoatomic oxygen, and OH species, and
in the step (3), through supply of the oxidizing gas, organometallic gas molecules adsorbed on the surface of the fine particles or on the surface of the metal oxide thin film formed on the surface of the fine particles are oxidized so as to form a metal oxide thin film, and OH groups are formed on the surface of the metal oxide thin film so as to hydrophilize the surface of the metal oxide thin film.

9. A metal oxide-coated fine particle having a diameter of the order of micrometers, wherein the fine particle has, on the surface thereof, a coating formed of a metal oxide thin film.

10. The metal oxide-coated fine particle according to claim 9, wherein the fine particle is zinc sulfide.

11. The metal oxide-coated fine particle according to claim 9, wherein the coating is formed of aluminum oxide.

12. The metal oxide thin film formation apparatus according to claim 2, wherein
the vacuum container has an opening formed in a side surface thereof and connected to the evacuation means, and
the relation S₁<S₂ holds, where S₁ is the area of the opening of the treatment container, and S₂ is the area of the opening of the vacuum container.

13. The metal oxide thin film formation apparatus according to claim 2, wherein
the oxidizing gas contains one or a plurality of species selected from the group consisting of noble gases, radicals of noble gas components, hydrogen radicals, monoatomic hydrogen, oxygen radicals, monoatomic oxygen, and OH species.

14. The metal oxide thin film formation apparatus according to claim 3, wherein
the oxidizing gas contains one or a plurality of species selected from the group consisting of noble gases, radicals of noble gas components, hydrogen radicals, monoatomic hydrogen, oxygen radicals, monoatomic oxygen, and OH species.

15. The metal oxide thin film formation apparatus according to claim 12, wherein
the oxidizing gas contains one or a plurality of species selected from the group consisting of noble gases, radicals of noble gas components, hydrogen radicals, monoatomic hydrogen, oxygen radicals, monoatomic oxygen, and OH species.

16. The metal oxide thin film formation method according to claim 6, wherein the step (1) and the step (3) are repeated while gas inside the vacuum container is always exhausted by the evacuation means.

17. The metal oxide thin film formation method according to claim 6, wherein
the oxidizing gas supplied by the oxidizing gas supplying means contains one or a plurality of species selected from the group consisting of noble gases, radicals of noble gas components, hydrogen radicals, monoatomic hydrogen, oxygen radicals, monoatomic oxygen, and OH species, and
in the step (3), through supply of the oxidizing gas, organometallic gas molecules adsorbed on the surface of the fine particles or on the surface of the metal oxide thin film formed on the surface of the fine particles are oxidized so as to form a metal oxide thin film, and OH groups are formed on the surface of the metal oxide thin film so as to hydrophilize the surface of the metal oxide thin film.

18. The metal oxide thin film formation method according to claim 7, wherein
the oxidizing gas supplied by the oxidizing gas supplying means contains one or a plurality of species selected from the group consisting of noble gases, radicals of noble gas components, hydrogen radicals, monoatomic hydrogen, oxygen radicals, monoatomic oxygen, and OH species, and
in the step (3), through supply of the oxidizing gas, organometallic gas molecules adsorbed on the surface of the fine particles or on the surface of the metal oxide thin film formed on the surface of the fine particles are oxidized so as to form a metal oxide thin film, and OH groups are formed on the surface of the metal oxide thin film so as to hydrophilize the surface of the metal oxide thin film.

19. The metal oxide thin film formation method according to claim 16, wherein
the oxidizing gas supplied by the oxidizing gas supplying means contains one or a plurality of species selected from the group consisting of noble gases, radicals of noble gas components, hydrogen radicals, monoatomic hydrogen, oxygen radicals, monoatomic oxygen, and OH species, and
in the step (3), through supply of the oxidizing gas, organometallic gas molecules adsorbed on the surface of the fine particles or on the surface of the metal oxide thin film formed on the surface of the fine particles are oxidized so as to form a metal oxide thin film, and OH groups are formed on the surface of the metal oxide thin film so as to hydrophilize the surface of the metal oxide thin film.

20. The metal oxide-coated fine particle according to claim 10, wherein the coating is formed of aluminum oxide.
